(19) United States
(12) Patent Application Publication
(10) Pub. No.: US 2005/0104208 A1
(43) Pub. Date: May 19, 2005

(54) STABILIZING COPPER OVERLAYER FOR ENHANCED C4 INTERCONNECT RELIABILITY

(75) Inventors: James C. Bartelo, Endicott, NY (US); Tien-Jen Cheng, Bedford, NY (US); David E. Eichstadt, North Salem, NY (US); Charles C. Goldsmith, Poughkeepsie, NY (US); Jonathan H. Griffith, LaGrangeville, NY (US); Donald W. Henderson, Ithaca, NY (US); Roger A. Quon, Rhinebeck, NY (US); Stephen Kilpatrick, Olney, MD (US)

Correspondence Address: FREDERICK W. GIBB, III;MCGINN & GIBB, PLLC, 2568-A RIVA ROAD, SUITE 304, ANNAPOLIS, MD, 21401, US

(73) Assignee: INTERNATIONAL BUSINESS MACHINES CORPORATION, ARMONK, NY (US)

(21) Appl. No.: 10/707,021

(22) Filed: Nov. 14, 2003

(51) Int. Cl. H01L 23/48

(52) U.S. Cl. 257/737

(57) ABSTRACT

Disclosed is an improved integrated circuit structure that has internal circuitry and interconnects (e.g. C4, etc.) on an external portion of the structure. With the invention, these interconnects have a metal layer on the external portion of the structure, a first copper layer on the metal layer, a barrier layer on the copper layer, a stabilizing copper layer on the barrier layer, and a tin-based solder bump on the barrier layer. The stabilizing copper layer has a sufficient amount of copper to balance the chemical potential gradient of copper across the barrier layer and prevent copper within the first copper layer from diffusing across the barrier layer. Alternatively, a sufficient amount of copper can be included within the tin-based solder bump to prevent copper from diffusing across the barrier layer. Thus, the tin-based solder bump comprises a copper rich solder alloy.

### BACKGROUND OF THE INVENTION

1. Field of the Invention

The invention generally relates to interconnect structures of integrated circuits and more particularly to an improved interconnect structure that reduces the likelihood of voiding and delamination.

2. Description of the Related Art

The reduction of device dimensions and increased clock speeds strain the limits of today's C4 interconnect technology. The higher current densities required of next generation technologies increases the likelihood of voiding and delamination in the ball-limiting metallurgy (BLM) interconnect structure of solder joints due to atomic diffusion processes. This failure mode is especially rapid for systems employing solders with high concentrations of tin (Sn), such as the leading lead-free solders as well as eutectic PbSn solder.

More specifically, copper diffusion across the barrier layers when using such solders increases the likelihood of delamination. The solder bump BLM structures are susceptible to reliability failures in the ball-limiting metallurgy (BLM) when used to support tin-containing solders. In such situations, copper will diffuse through the barrier metallurgy and into the solder, leaving the layer of copper voided and depleted. This migration of the BLM copper is driven by the chemical potential gradient across the barrier layer. Elemental copper is unstable in the presence of tin, preferring to form intermetallic compounds such as Cu₃Sn or Cu(Ni)₆Sn₅. The invention described below allows the use of such solders while substantially decreasing the likelihood of copper diffusion across barrier layers. Therefore, the invention substantially reduces the likelihood of voiding and delamination, which increases yield and reliability.

### SUMMARY OF THE INVENTION

The invention provides an improved integrated circuit structure that has internal circuitry and interconnects (e.g. C4, etc.) on an external portion of the structure. With the invention, these interconnects have a metal layer on the external portion of the structure, a first copper layer on the metal layer, a barrier layer on the copper layer, a stabilizing copper layer on the barrier layer, and a tin-based solder bump on the barrier layer. The stabilizing copper layer has a sufficient amount of copper to balance the chemical potential gradient of copper across the barrier layer and prevent copper within the first copper layer from diffusing across the barrier layer. Alternatively, a sufficient amount of copper can be included within the tin-based solder bump to prevent copper from diffusing across the barrier layer. Thus, the tin-based solder bump comprises a copper rich solder alloy. The metal layer comprises diffusion metallurgy including one or more of Al, Ti, TiW, Cr, Ta, and TaN. The barrier layer can be Ni, V, or NiV. The tin-based solder bump can be either a eutectic PbSn solder or a lead-free solder.

The invention introduces a sufficient amount of copper in the solder above the barrier layer to prevent this unwanted diffusion. This significantly reduces the diffusion of elemental copper through the barrier layer. In effect, the introduction of copper reduces the chemical potential gradient of copper across the barrier layer. Reduction of this chemical potential gradient decreases the diffusive flux of elemental copper through the barrier layer, even at elevated temperatures. In this manner, the serviceability requirements of the application in question are consequently enhanced.

Thus, the invention controls the composition of the solder alloy (for the additional copper layer) to protect against voiding of BLM-layered structures and delamination to the diffusion of copper. This BLM barrier technology enables the use of higher current densities for advanced CMOS designs, and extends the reliability of current CMOS designs. Moreover, this technology is easily adopted by current methods for fabricating C4s.

### BRIEF DESCRIPTION OF THE DRAWINGS

The invention will be better understood from the following detailed description with reference to the drawings, in which:

FIG. 1 is a schematic diagram of an interconnect structure;

FIG. 2 is a schematic diagram of an interconnect structure;

FIG. 3 is a schematic diagram of an interconnect structure; and

FIG. 4 is a schematic diagram of an interconnect structure.

### DETAILED DESCRIPTION OF PREFERRED EMBODIMENTS OF THE INVENTION

The invention provides a structure that controls the composition of the solder alloy to protect against voiding of BLM-layered structures and delamination to the diffusion of copper, whether such diffusion is caused by self-diffusion or enhanced self-diffusion by such processes as electro-migration or thermo-migration. This BLM barrier technology enables the use of higher current densities for advanced CMOS designs, and extends the reliability of current CMOS designs. Moreover, this technology is easily adopted by current methods for fabricating C4s.

As explained above, C4 bump BLM structures are susceptible to reliability failures in the ball-limiting metallurgy (BLM) when used to support tin-containing solders because the copper will diffuse through the barrier metallurgy and into the solder, leaving the layer of copper voided and depleted. This migration of the BLM copper is driven by the chemical potential gradient across the barrier layer, which results because elemental copper is unstable in the presence of tin, preferring to form intermetallic compounds such as Cu3Sn or Cu(Ni)6Sn5.

The invention introduces a sufficient amount of copper in the solder above the barrier layer to prevent this unwanted diffusion. This significantly reduces the diffusion of elemental copper through the barrier layer. In effect, the introduction of copper reduces the chemical potential gradient of copper across the barrier layer. Reduction of this chemical potential gradient decreases the diffusive flux of elemental copper through the barrier layer, even at elevated temperatures. In this manner, the serviceability requirements of the application in question are consequently enhanced.

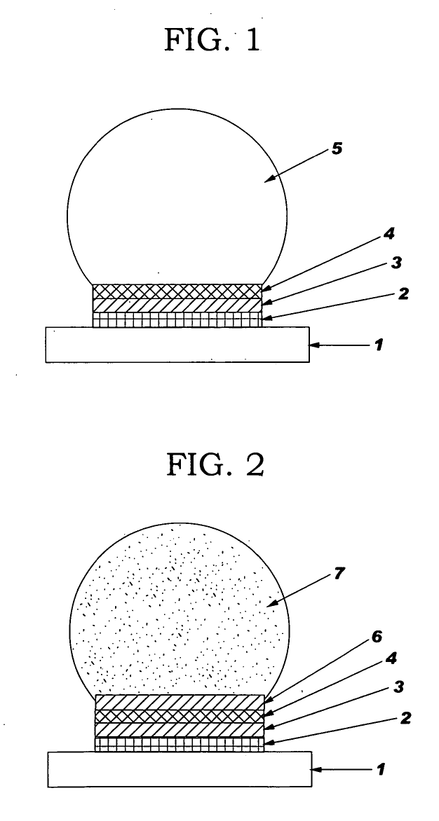

FIG. 1 illustrates a C4 BLM interconnect structure that is formed on an external portion of the structure (e.g., substrate) 1. These interconnects have a metal layer 2 on the substrate, a first copper layer 3 on the metal layer 2, a barrier layer 4 on the copper layer 3, and a tin-based solder bump 5 on the barrier layer. The metal layer 2 comprises diffusion metallurgy including one or more of Al, Ti, TiW, Cr, Ta, and TaN. The barrier layer 4 can be Ni, V, or NiV. The tin-based solder bump 5 can be either a eutectic PbSn solder or a lead-free solder.

As discussed above, the copper 3 is strongly attracted to the solder bump 5 because of the chemical potential gradient. If the copper 3 diffuses across the barrier layer 4 into the solder bump 5, this will create voids within the copper layer 3, which substantially increases the likelihood of delamination.

FIG. 2 illustrates the addition of a stabilizing copper layer 6 that has a sufficient amount of copper to balance the chemical potential gradient of copper across the barrier layer and prevent copper within the first copper layer from diffusing across the barrier layer. After annealing processes, some of the copper diffuses from layer 6 into the solder bump 7. Thus, the tin-based solder bump 7 comprises a copper rich solder alloy.

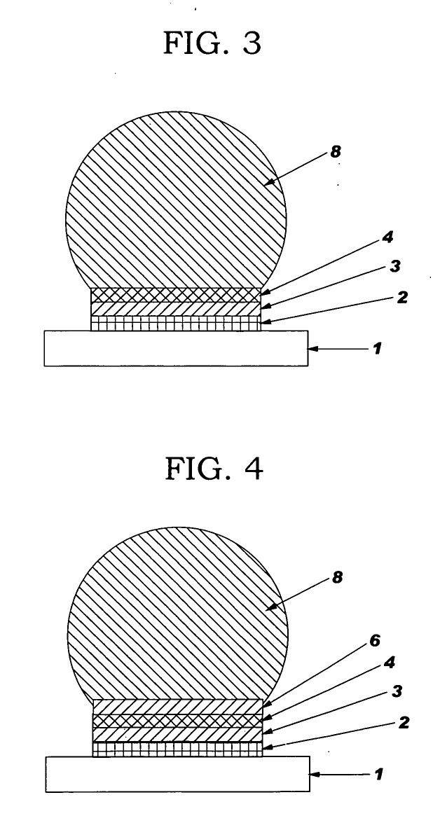

Alternatively, as shown in FIG. 3 a sufficient amount of copper can be included within the tin-based solder bump 8 to prevent copper from diffusing across the barrier layer, thereby eliminating the need for a distinct, separate copper layer 6. Additionally, if desired, as shown in FIG. 4, the invention can include the tin-based solder bump 8 and a separate copper layer 6, depending upon the volume of copper required by the individual designer's requirements.

The addition of Cu to the solder 8 may be accomplished in several ways, including: directly alloying the solder before application to the BLM structure, plating Cu as part of the solder alloy onto the BLM structure of introducing a stabilizing Cu layer 6 over the barrier layer 4 before applying the Sn based solder. All of these methods enable the alloying of the solder with Cu. In doing so, the chemical potential of Cu is raised in the solder and the diffusion through the barrier layer is reduced.

During the reflow processing of the chip, the solder will dissolve substantial amounts of Cu from the stabilizing layer 6, thus raising the Cu content of the solder 7 and producing a Cu rich solder alloy. This increase in the Cu concentration in the solder dramatically decreases the Cu Diffusion through the barrier layer 4. Therefore, the invention substantially reduces the likelihood of voiding and delamination, which increases yield and reliability.

Thus, as shown above, the invention introduces a sufficient amount of copper in the solder above the barrier layer to prevent this unwanted diffusion. This significantly reduces the diffusion of elemental copper through the barrier layer. In effect, the introduction of copper reduces the chemical potential gradient of copper across the barrier layer. Reduction of this chemical potential gradient decreases the diffusive flux of elemental copper through the barrier layer, even at elevated temperatures. In this manner, the serviceability requirements of the application in question are consequently enhanced.

Thus, the invention controls the composition of the solder alloy (for the additional copper layer) to protect against voiding of BLM-layered structures and delamination to the diffusion of copper. This BLM barrier technology enables the use of higher current densities for advanced CMOS designs, and extends the reliability of current CMOS designs. Moreover, this technology is easily adopted by current methods for fabricating C4s.

While the invention has been described in terms of preferred embodiments, those skilled in the art will recognize that the invention can be practiced with modification within the spirit and scope of the appended claims.

1. A solder interconnect used with an integrated circuit structure, said interconnect comprising:
a metal layer on a substrate;
a first copper layer on said metal layer;
a barrier layer on said copper layer;
a stabilizing copper layer on said barrier layer; and
a tin-based solder bump on said barrier layer,
wherein said tin-based solder bump comprises a lead-fee solder, and
wherein said stabilizing copper layer comprises an amount of copper sufficient to balance the chemical potential gradient of copper across said barrier layer.

2. The interconnect in claim 1, wherein said stabilizing copper layer comprises a sufficient amount of copper to prevent copper within said first copper layer from diffusing across said barrier layer.

3. The interconnect in claim 1, wherein said tin-based solder bump comprises a copper rich solder alloy.

4. The interconnect in claim 1, wherein said metal layer comprises diffusion metallurgy including at least one of Al, Ti, TiW, Cr, Ta, and TaN.

5. The interconnect in claim 1, wherein said barrier layer comprises one of Ni, V, and NiV.

6. (canceled)

7. A solder interconnect used with an integrated circuit structure, said interconnect comprising:
a metal layer on a substrate;
a first copper layer on said metal layer;
a barrier layer on said copper layer;
a copper and tin-based solder alloy bump on said barrier layer,
wherein said copper and tin-based solder alloy bump comprises a lead-free solder and
wherein said copper and tin-based solder alloy bump comprises an amount of copper sufficient to balance the chemical potential gradient of copper across said barrier layer.

8. The interconnect in claim 7, wherein said copper and tin-based solder alloy bump comprises a sufficient amount of copper to prevent copper within said first copper layer from diffusing across said barrier layer.

9. The interconnect in claim 7, wherein said metal layer comprises diffusion metallurgy including at least one of Al, Ti, TiW, Cr, Ta, and TaN.

10. The interconnect in claim 7, wherein said barrier layer comprises one of Ni, V, and NiV.

11. (canceled)

12. An integrated circuit structure comprising:
internal circuitry; and
an interconnect on an external portion of said structure, said interconnect comprising:
a metal layer on said external portion of said structure;
a first copper layer on said metal layer,
a barrier layer on said copper layer;
a stabilizing copper layer on said barrier layer; and
a tin-based solder bump on said barrier layer,
wherein said tin-based solder bump comprises a lead-free solder, and
wherein said stabilizing copper layer comprises an amount of copper sufficient to balance the chemical potential gradient of copper across said barrier layer.

13. The structure in claim 12, wherein said stabilizing copper layer comprises a sufficient amount of copper to prevent copper within said fist copper layer from diffusing across said barrier layer.

14. The structure in claim 12, wherein said tin-based solder bump comprises a copper rich solder alloy.

15. The structure in claim 12, wherein said metal layer comprises diffusion metallurgy including at least one of Al, Ti, TiW, Cr, Ta, and TaN.

16. The structure in claim 12, wherein said barrier layer comprises one of Ni, V, and NiV.

17. (canceled)

18. An integrated circuit structure comprising:
internal circuitry; and
an interconnect on an external portion of said structure, said interconnect comprising:
a metal layer on said external portion of said structure;
a first copper layer on said metal layer;
a barrier layer on said copper layer;
a copper and tin-based solder alloy bump on said barrier layer,
wherein said copper and tin-based solder alloy bump comprises a lead-free solder, and
wherein said copper and tin-based solder alloy bump comprises an amount of copper sufficient to balance the chemical potential gradient of copper across said barrier layer.

19. The structure in claim 18, wherein said copper and tin-based solder alloy bump comprises a sufficient amount of copper to prevent copper within said first copper layer from diffusing across said barrier layer.

20. The structure in claim 18, wherein said metal layer comprises diffusion metallurgy including at least one of Al, Ti, TiW, Cr, Ta, and TaN.

21. The structure in claim 18, wherein said barrier layer comprises one of Ni, V, and NiV.

22. (canceled)
